(19) United States
(12) Patent Application Publication
(10) Pub. No.: US 2019/0170681 A1
(43) Pub. Date: Jun. 6, 2019

(54) SYSTEMS AND METHODS FOR ELECTRICAL SENSING OF BIOMOLECULAR TARGETS

(71) Applicant: Integrated Nano-Technologies, Inc., Henrietta, NY (US)

(72) Inventors: Nathaniel E. Wescott, West Henrietta, NY (US); Dennis M. Connolly, Rochester, NY (US); Richard S. Murante, Rochester, NY (US)

(73) Assignee: Integrated Nano-Technologies, Inc., Henrietta, NY (US)

(21) Appl. No.: 16/324,974

(22) PCT Filed: Aug. 15, 2017
(86) PCT No.: PCT/US2017/046877

§ 371 Date: Feb. 12, 2019

Related U.S. Application Data
(60) Provisional application No. 62/374,985, filed on Aug. 15, 2016.

(51) Int. Cl. G01N 27/414

(52) U.S. Cl. CPC G01N 27/4145; H01L 29/16; G01N 27/4146

(57) ABSTRACT

A system for detection of a target molecule includes a source terminal, a drain terminal, a gate positioned between the source terminal and the drain terminal, and a functionalized sensor surface between the source terminal and the drain terminal and adjacent to the gate. The sensor surface is configured to bind target molecules and the target molecules are configured to bind functionalized nanoparticles. A sensor is coupled to the source terminal and drain terminal to monitor changes in electrical signals and detect the target molecules when changes in the electrical signals are detected.

### CROSS-REFERENCE TO RELATED APPLICATIONS

This application claims the benefit of and priority to U.S. Provisional Patent Application Ser. No. 62/374,985, filed Aug. 15, 2016 and entitled “TECHNIQUES FOR ELECTRICAL SENSING OF BIOMOLECULAR TARGETS,” the entirety of which is incorporated herein by reference.

### BACKGROUND

The subject matter disclosed herein relates to a detecting target molecules, such as nucleic acid molecules and, more particularly, to systems for electrical sensing of the target molecules.

Various methods have developed for analyzing biological samples and detecting the presence of target molecules, such as nucleic acid molecules. These methods can be used, for example, in detecting pathogens in samples.

Typically, detection methods use disruption techniques, such as Polymerase Chain Reaction (PCR) to extract and replicate nucleic acid molecules from a sample. PCR is a technique that allows for replicating and amplifying trace amounts of DNA fragments into quantities that are sufficient for analysis. As such, PCR can be used in a variety of applications, such as DNA sequencing and detecting DNA fragments in samples.

An electronic sensor for detection of specific target nucleic acid molecules can include capture probes immobilized on a sensor surface between a set of paired electrodes. An example of a system and method for detecting target nucleic acid molecules is described in U.S. Pat. No. 7,645,574, the entirety of which is herein incorporated by reference. Following PCR, amplified products or amplicons derived from targeted pathogen sequences are captured by the probes Nano-gold clusters, functionalized with a complementary sequence, are used for localized hybridization to the amplicons. Subsequently, using a short treatment with a gold developer reagent, the nano-gold clusters serve as catalytic nucleation sites for metallization, which cascades into the development of a fully conductive film. The presence of the gold film shorts the gap between the electrodes and is measured by a drop in resistance, allowing the presence of the captured amplification products to be measured. However, such sensors can be insensitive to small quantities of target molecules, resulting in false negative results or a failure to detect the target molecules.

### SUMMARY

A system for detection of a target molecule includes a source terminal, a drain terminal, a gate positioned between the source terminal and the drain terminal, and a functionalized sensor surface between the source terminal and the drain terminal. The sensor surface is configured to bind target molecules and the target molecules are configured to bind functionalized nanoparticles. A sensor is coupled to the source terminal and drain terminal to monitor changes in electrical signals and detect the target molecules when changes in the electrical signals are detected.

In an embodiment, a system for detecting a target molecule in a sample is disclosed. The system includes a source terminal, a drain terminal, a sensor coupled to the source terminal and the drain terminal. The sensor is configured to monitor electrical signals across the source terminal and drain terminal. A gate is positioned adjacent to one of the source terminal and the drain terminal and extends partially across a gap between the source terminal and drain terminal. A sensor surface is exposed between the gate and one of the source terminal and the drain terminal. The sensor surface is a functionalized sensor surface configured to bind the target molecule.

A sensor surface is positioned between the source terminal and the drain terminal. The sensor surface includes a functionalized sensor surface configured to bind the target molecule. A gate is positioned adjacent to one of the source terminal and the drain terminal and extends partially across the sensor surface.

In another embodiment, a system for detecting a target molecule in a sample is disclosed. The system includes a source terminal, a drain terminal, and a sensor coupled to the source terminal and the drain terminal. The sensor is configured to monitor electrical signals across the source terminal and drain terminal. A gate is positioned between the source terminal and the drain terminal and a channel is positioned above the gate. The channel includes a functionalized sensor surface configured to bind the target molecule.

In yet another embodiment, a system for detecting a target molecule in a sample is disclosed. The system includes a substrate, a first transducer positioned on the substrate, and a second transducer positioned on the substrate. The first transducer has a signal input and the second transducer has a signal output. A sensor is coupled to the signal input to input a signal and to the signal output to measure an output signal. A delay area is positioned between the first transducer and the second transducer. The delay area has a functionalized coating configured to bind the target molecule.

An advantage that may be realized in the practice of some disclosed embodiments is increased sensitivity of nucleic acid sensors and improved detection of low concentrations of target materials.

The above embodiments are exemplary only. Other embodiments are within the scope of the disclosed subject matter.

### BRIEF DESCRIPTION OF THE DRAWINGS

So that the manner in which the features of the invention can be understood, a detailed description of the invention may be had by reference to certain embodiment, some of which are illustrated in the accompanying drawings. It is to be noted, however, that the drawings illustrate only certain embodiments of this invention and are therefore not to be considered limiting of its scope, for the scope of the disclosed subject matter encompasses other embodiments as well. The drawings are not necessarily to scale, emphasis generally being placed upon illustrating the features of certain embodiments of the invention. In the drawings, like numerals are used to indicate like parts throughout the various views.

FIG. 1 is a perspective view of a portable diagnostic assay system operative to accept one of a plurality of disposable cartridges configured to test fluid samples of collected blood/food/biological samples;

FIG. 2 is an exploded perspective view of one of the disposable cartridges configured to test a blood/food/biological sample;

FIG. 3 is a top view of the one of the disposable cartridges illustrating a variety of assay chambers including a central assay chamber, one of which contains an assay chemical suitable to breakdown the fluid sample to detect a particular attribute of the tested fluid sample;

FIG. 4 is a bottom view of the disposable cartridge shown in FIG. 3 illustrating a variety of channels operative to move at least a portion of the fluid sample from one chamber to another for the purpose of performing multiple operations on the fluid sample.

FIG. 5 is an illustration of an embodiment of a functionalized sensor surface;

FIG. 6 is an illustration of the sensor surface of FIG. 5 having the target molecule coupled thereto;

FIG. 7 is an illustration of the sensor surface of FIG. 6 with a nanoparticle coupled to the captured target molecule;

FIG. 8 is an illustration of the sensor surface of FIG. 7 with a conductive film formed over the nanoparticles;

FIG. 9A is a top view illustration of an embodiment of a detection system;

FIG. 9B is a cross-sectional illustration of the detection system of FIG. 9A;

FIG. 10 is a flowchart illustrating an embodiment of a method of detecting a target molecule;

FIG. 11A is a top view illustration of the detection system of FIG. 9A with catalytic nanoparticles bound to captured target molecules on the sensor surface;

FIG. 11B is a cross-sectional illustration of the detection system of FIG. 11A;

FIG. 12A is a top view illustration of the detection system of FIG. 11A with a conductive film formed over the catalytic nanoparticles;

FIG. 12B is a cross-sectional illustration of the detection system of FIG. 12A;

FIG. 13A is a cross-sectional illustration of an embodiment of a detection system with target molecules bound to a sensor surface;

FIG. 13B is a cross-sectional illustration of the detection system of FIG. 13A with catalytic nanoparticles bound to the target molecules;

FIG. 13C is a cross-sectional illustration of the detection system of FIG. 13B with a conductive film formed over the catalytic nanoparticles;

FIG. 14 is a flowchart illustrating another embodiment of a method of detecting a target molecule;

FIG. 15A is a top view illustration of an embodiment of a detection system;

FIG. 15B is a cross-sectional illustration of the detection system of FIG. 16A with target molecules bound to a functionalized sensor surface;

FIG. 15C is a cross-sectional illustration of the detection system of FIG. 16B with catalytic nanoparticles bound to the target molecules; and

FIG. 15D is a cross-sectional illustration of the detection system of FIG. 16C with a conductive film over the catalytic nanoparticles.

Corresponding reference characters indicate corresponding parts throughout several views. The examples set out herein illustrate several embodiments, but should not be construed as limiting in scope in any manner.

### DETAILED DESCRIPTION

A disposable cartridge is described for use in a portable/automated assay system such as that described in commonly-owned, co-pending U.S. patent application Ser. No. 15/157,584 filed May 18, 2016 entitled “Method and System for Sample Preparation” which is hereby included by reference in its entirety. While the principal utility for the disposable cartridge includes DNA testing, the disposable cartridge may be used to detect any of a variety of diseases which may be found in either a blood, food or biological detecting hepatitis, autoimmune deficiency syndrome (AIDS/HIV), diabetes, leukemia, graves, lupus, multiple myeloma, etc., just naming a small fraction of the various blood borne diseases that the portable/automated assay system may be configured to detect. Food diagnostic cartridges may be used to detect salmonella, e-coli, staphylococcus aureus or dysentery. Diagnostic cartridges may also be used to test samples from insects and specimen. For example, blood diagnostic cartridges may be dedicated cartridges useful for animals to detect diseases such as malaria, encephalitis and the west nile virus, to name but a few.

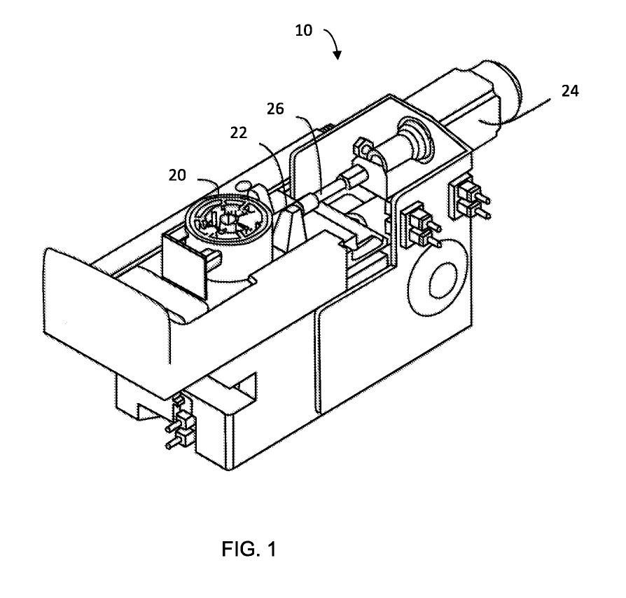

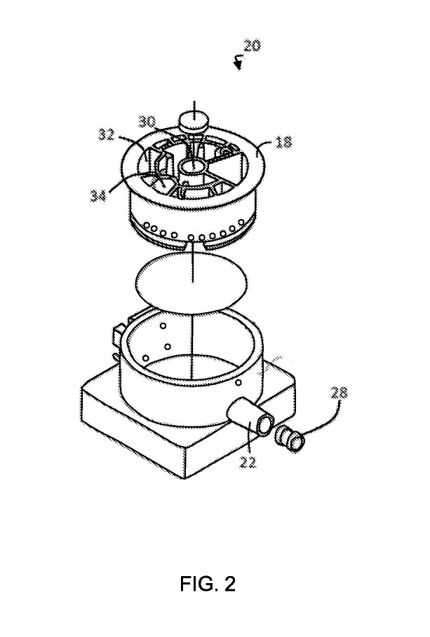

More specifically, and referring to FIGS. 1 and 2, a portable assay system 10 receives any one of a variety of disposable assay cartridges 20, each selectively configured for detecting a particular attribute of a fluid sample, each attribute potentially providing a marker for a blood, food or biological (animal borne) disease. The portable assay system 10 includes one or more linear and rotary actuators operative to move fluids into, and out of, various compartments or chambers of the disposable assay cartridge 20 for the purpose of identifying or detecting a fluid attribute. More specifically, a signal processor 14, i.e., a PC board, controls a rotary actuator (not shown) of the portable assay system 10 so as to align one of a variety of ports 18P, disposed about a cylindrical rotor 18, with a syringe barrel 22B of a stationary cartridge body 22. The processor 14 controls a linear actuator 24, to displace a plunger shaft 26 so as to develop pressure i.e., positive or negative (vacuum) in the syringe barrel 22. That is, the plunger shaft 26 displaces an elastomer plunger 28 within the syringe 22 to move and or admix fluids contained in one or more of the chambers 30, 32.

The disposable cartridge 20 provides an automated process for preparing the fluid sample for analysis and/or performing the fluid sample analysis. The sample preparation process allows for disruption of cells, sizing of DNA and RNA, and concentration/clean-up of the material for analysis. More specifically, the sample preparation process of the instant disclosure prepares fragments of DNA and RNA in a size range of between about 100 and 10,000 base pairs. The chambers can be used to deliver the reagents necessary for end-repair and kinase treatment. Enzymes may be stored dry and rehydrated in the disposable cartridge 20, or added to the disposable cartridge 20, just prior to use. The implementation of a rotary actuator allows for a single plunger 26, 28 to draw and dispense fluid samples without the need for a complex system of valves to open and close at various times. This greatly reduces potential for leaks and failure of the device compared to conventional systems. Finally, it will also be appreciated that the system greatly diminishes the potential for human error.

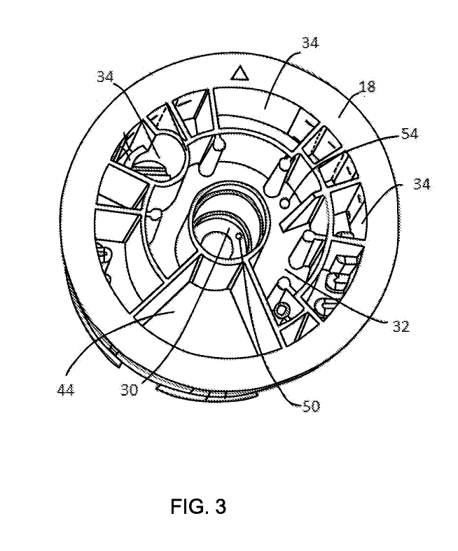

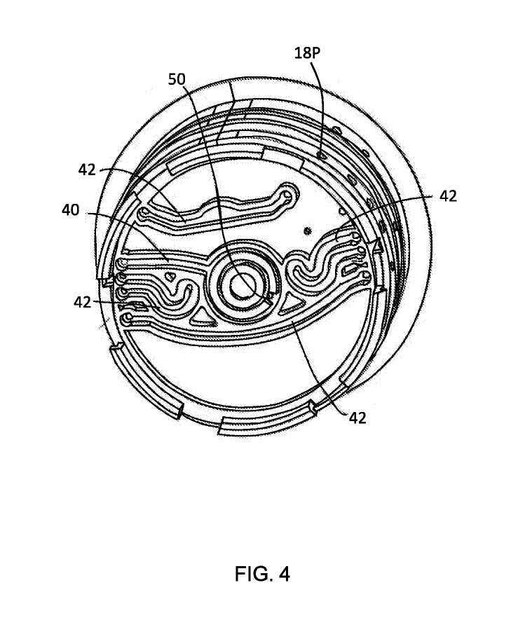

In FIGS. 3 and 4, the cylindrical rotor 18 includes a central chamber 30 and a plurality of assay chambers 32, 34 surrounded, and separated by, one or more radial or circumferential walls. In the described embodiment, the central chamber 30 receives the fluid sample while the surrounding chambers 32, 34 contain a premeasured assay chemical or reagent for the purpose of detecting an attribute of the fluid sample. The chemical or reagents may be initially dry and rehydrated immediately prior to conducting a test. Some of the chambers 32, 34 may be open to allow the introduction of an assay chemical while an assay procedure is underway or in-process. The chambers 30, 32, 34 are disposed in fluid communication, i.e., from one of the ports 18P to one of the chambers 30, 32, 34, by channels 40, 42 molded along a bottom panel 44, i.e., along underside surface of the rotor 18. For example, a first port 18P, corresponding to aperture 42, may be in fluid communication with the central chamber 30, via aperture 50.

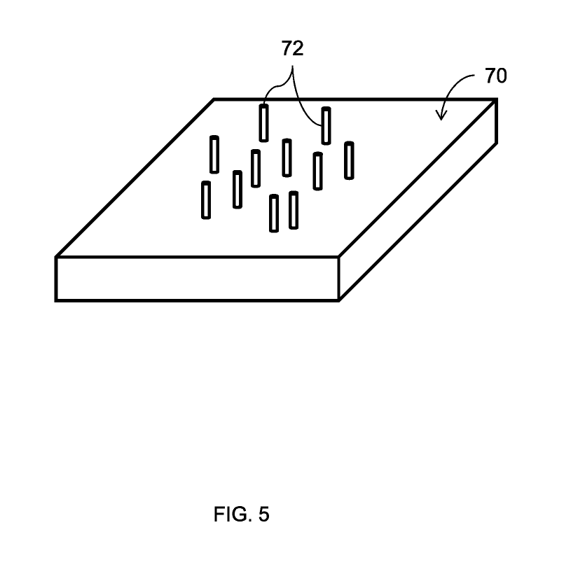

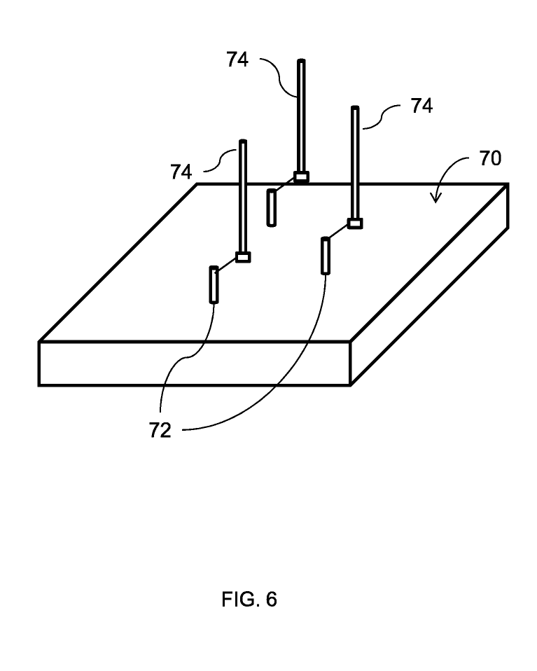

FIG. 5 illustrates an embodiment of a sensor surface 70. The sensor surface 70 includes a plurality of capture probes 72 in the form of a functionalized oxide surface allowing attachment and immobilization of capture probe molecules 72 on the sensor surface 70. The capture probes 72 are designed to capture or bind target molecules 74 (FIG. 6) by interaction between complementary sequences. The target molecules 74 can be collected from a biological sample. The biological sample could be any suitable type of material, such as blood, mucous, and skin, among others.

In an embodiment, a sample including the target molecules 74 is mixed with a solution containing magnetic nanoparticles (not shown) and the target molecules 74 and magnetic nanoparticles hybridize. Using a magnet (not shown), the hybridized target molecules are attracted to the functionalized sensor surface 70 for binding to the capture probe molecules 72.

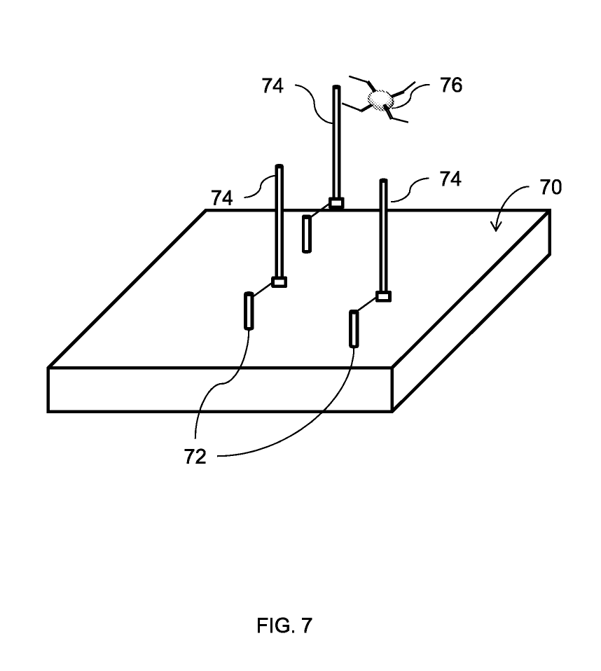

After the target molecules 74 are bound to or captured by the capture probe molecules 72 (FIG. 6), a catalytic nanoparticle 76, such as a gold catalyst reagent, is directly hybridized to the captured or bound target molecules 74, as illustrated in FIG. 7. Any suitable method of hybridizing the catalytic nanoparticles 76 and target molecules 74 can be used. In an embodiment, the catalytic nanoparticles 76 are in the form of catalyst clusters. In an embodiment, a single catalyst cluster 76 binds to each captured target molecule 74. In another embodiment, and depending on the length of the target molecule 74, a plurality of catalyst clusters 76 bind to each captured target molecule 74.

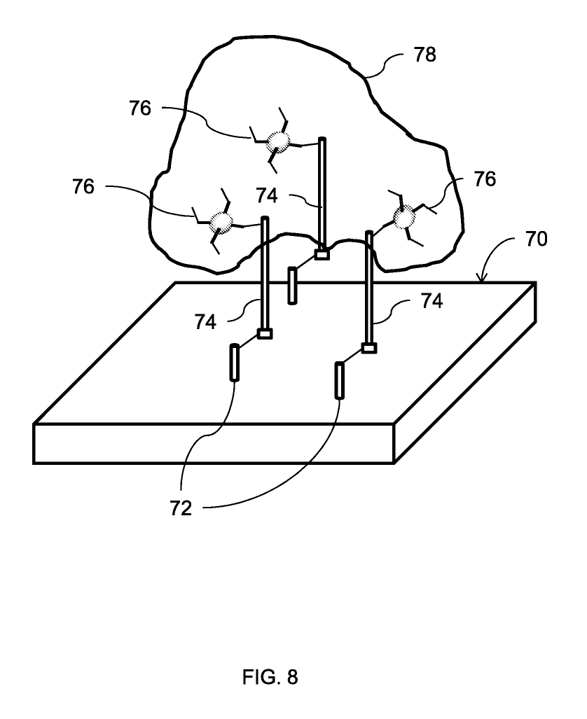

Following hybridization of the captured target molecules 74 with the catalytic nanoparticles 76, metallization of the catalytic nanoparticles 76, which serve as catalytic nucleation sites, can be performed to form a conductive film 78 (FIG. 8) that can be used to detect the target molecules 74. In an example, the catalytic nanoparticles 76 are gold clusters and a gold developer reagent is applied to the catalyst clusters to cascade into the development of the conductive film 78, which in this example is a gold film.

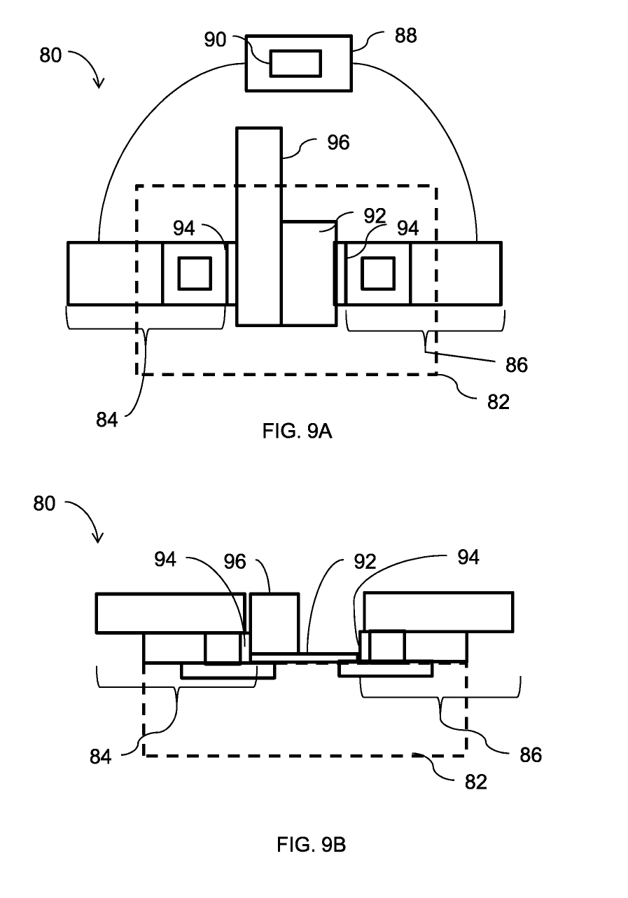

FIGS. 9A-9B illustrate an embodiment of a detection system 80 for detecting a target molecule 76. The system includes a well 82 on which are formed a source terminal 84 and a drain terminal 86. A sensor 88 is coupled to the source terminal 84 and drain terminal 86. The sensor 88 includes a microcontroller 90 for applying an electrical signal to the source terminal 84 and for measuring resistance across the source terminal 84 and drain terminal 86. A functionalized sensor surface 92 is positioned between the source terminal 84 and drain terminal 86 and separated from the source terminal 84 and drain terminal 86 by spacers 94. Similar to the sensor surface 70 described above (FIG. 5), the functionalized sensor surface 92 includes a plurality of capture probes (not shown) in the form of a functionalized oxide surface allowing attachment and immobilization of capture probe molecules on the sensor surface 92. In an embodiment, the spacers 94 can be formed of an insulating material, such as silicon dioxide, silicon oxynitride, or a high-K dielectric material.

A gate 96 is separated from the source terminal 84 by the spacer 94 and extends partially across a gap between the source terminal 84 and drain terminal 86 toward the drain terminal 86, exposing the functionalized sensor surface 92. Alternatively, the gate 96 can be separated from the drain terminal 86 by the spacer 94 and extend toward the source terminal 84. The gate 96 can be formed from a metal material or from a polysilicon (polycrystalline silicon). In an embodiment, the system 80 is in the form of an incomplete metal oxide semiconductor field effect transistor (MOSFET) in which the gate 97 is incomplete, exposing a portion of the gate dielectric. In one embodiment, the gate 96 is formed as a complete gate extending across the gap and a portion of the gate 96 is removed. In another embodiment, the gate 96 is formed as a partial gate.

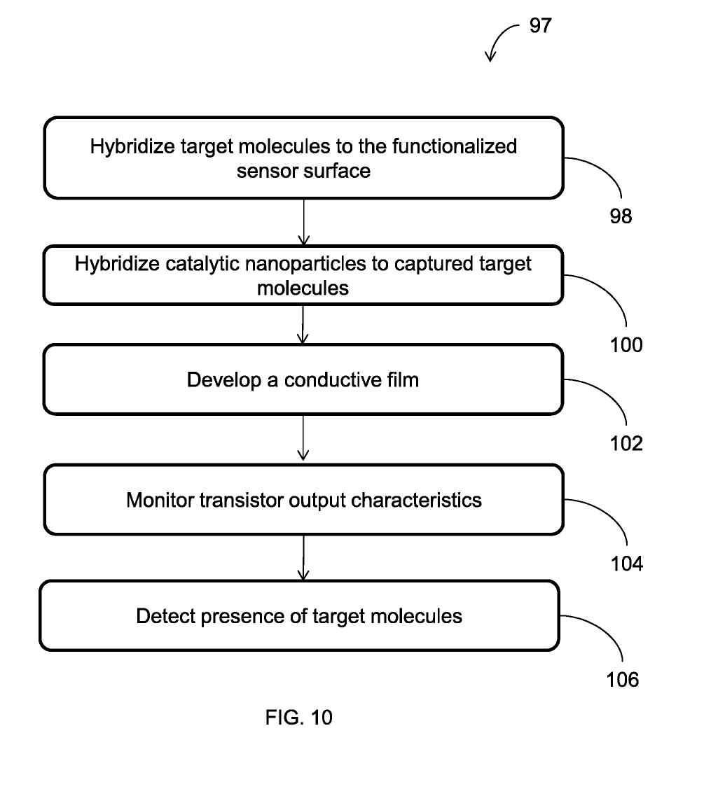

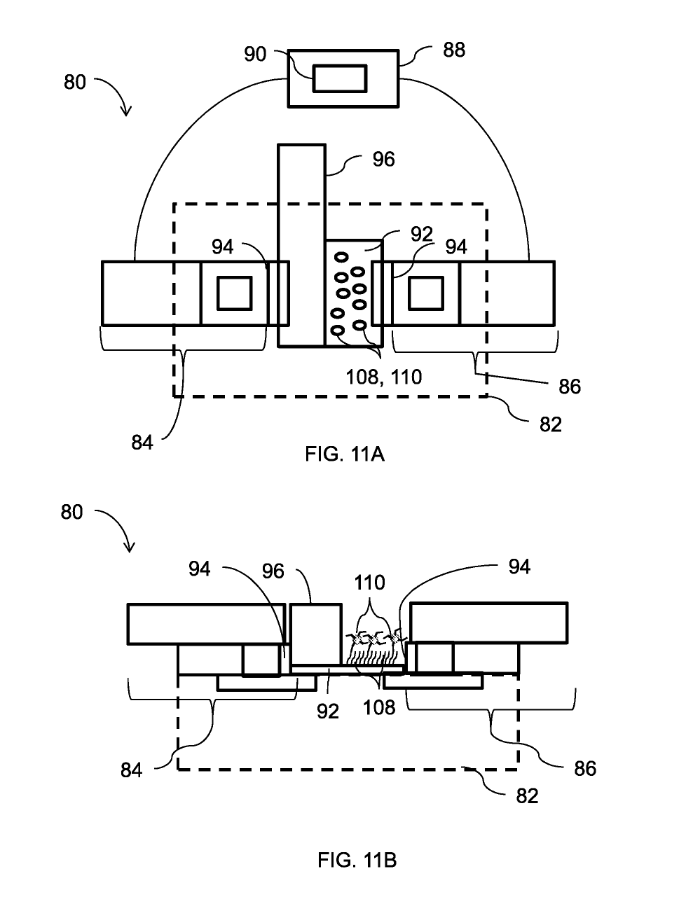

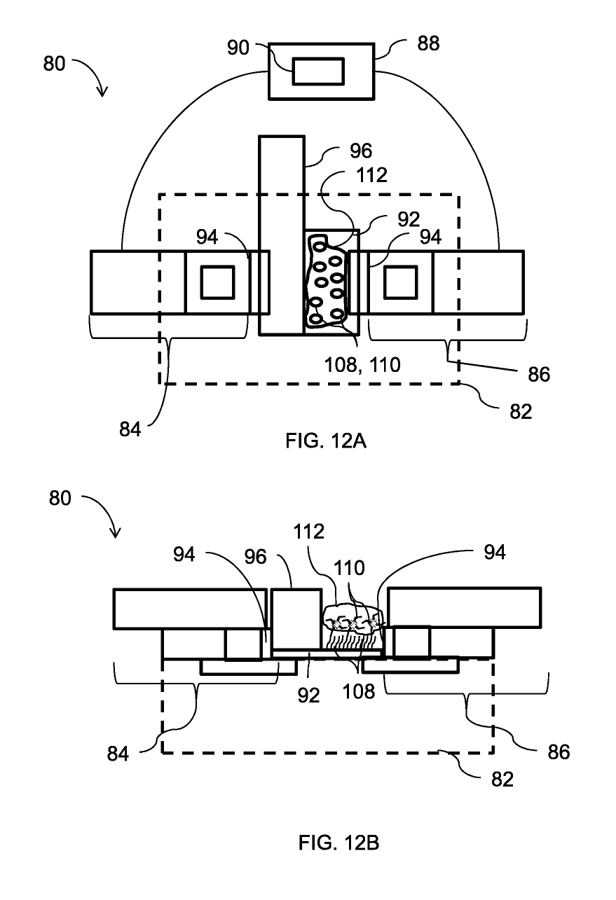

FIG. 10 illustrates an embodiment of a method 96 of detecting a target molecule with a detection system, such as the detection system 80 (FIGS. 9A-9B). At block 98, target molecules 108 are hybridized or bound to the functionalized sensor surface 92, as illustrated in FIGS. 11A-11B. In particular, the target molecules 108 are bound to capture molecules on the functionalized sensor surface 92.

At block 100 of the method 96 (FIG. 10), catalytic nanoparticles 110 are hybridized or bound to the captured target molecules 108. The hybridization of the catalytic nanoparticles 110 creates more “gate” material, extending the gate 96 across the sensor surface 92.

At block 102, a conductive film 112 can be formed by applying a reagent to the catalytic nanoparticles 110. For example, a bath can be applied to the catalytic nanoparticles to initiate development of the conductive film 112. In an embodiment, the catalytic nanoparticles 110 are gold clusters that act as nucleation sites for the development of a gold film. The conductive film 112 can further increase the development of the gate material, bridging the gap between the gate 96 and the drain terminal 86 or source terminal 84 and completing the MOSFET. In an embodiment, development of the conductive film 112 is optional.

At block 104 (FIG. 10) the sensor 88 (FIG. 9A) monitors transistor output characteristics to determine (block 106) the presence of target molecules 108. For example, if a change in voltage is detected, target molecules, catalytic nanoparticles, and, optionally, a conductive film have been deposited on the sensor surface 92, bridging the gap between the gate 96 and the source terminal 84 or the drain terminal 86, thus indicating the presence of the target molecules. By contrast, if no change in voltage is detected, the gap between the gate 96 and the source terminal 84 or drain terminal 86 has not been bridged, indicating that no target molecules 108 are present. While monitoring has been described in the context of voltage, it is to be understood that other characteristics of electrical signals can be monitored in order to detect the presence of target molecules. Various techniques, such as drain biasing, can be applied for partial metallization or higher sensitivity situations.

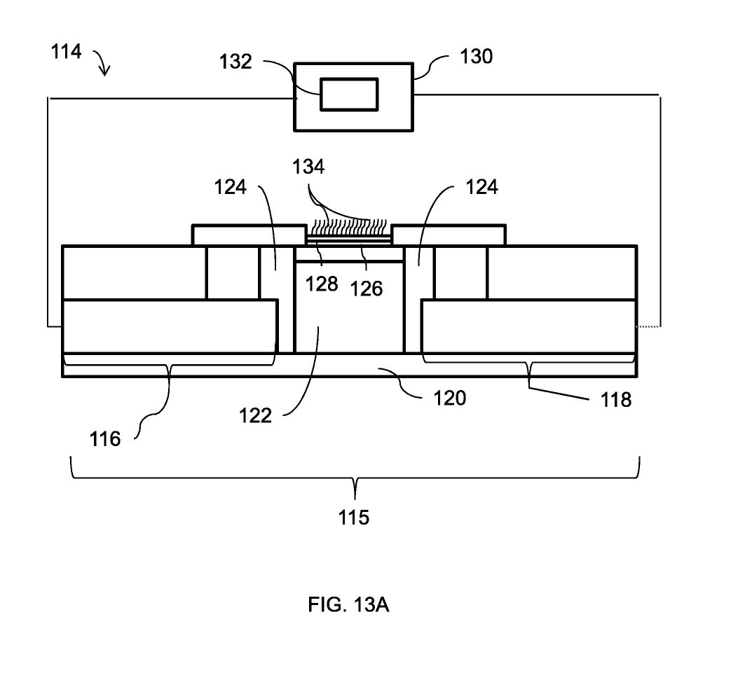

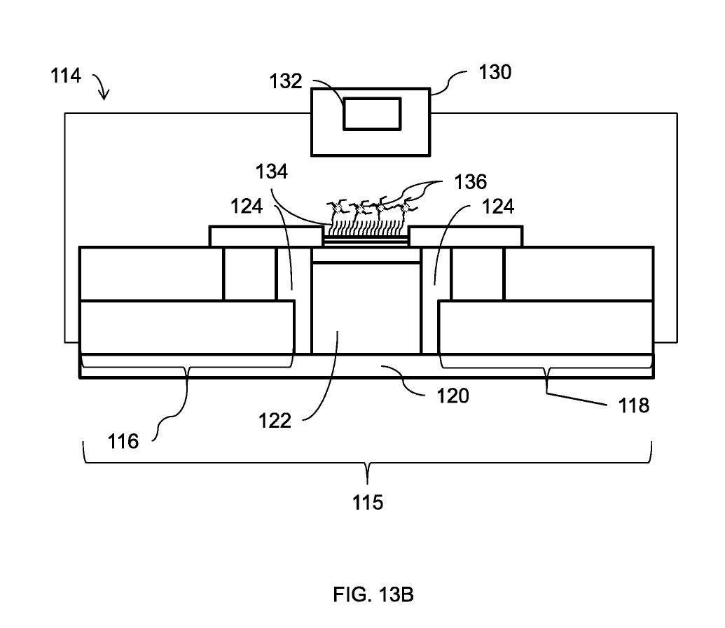

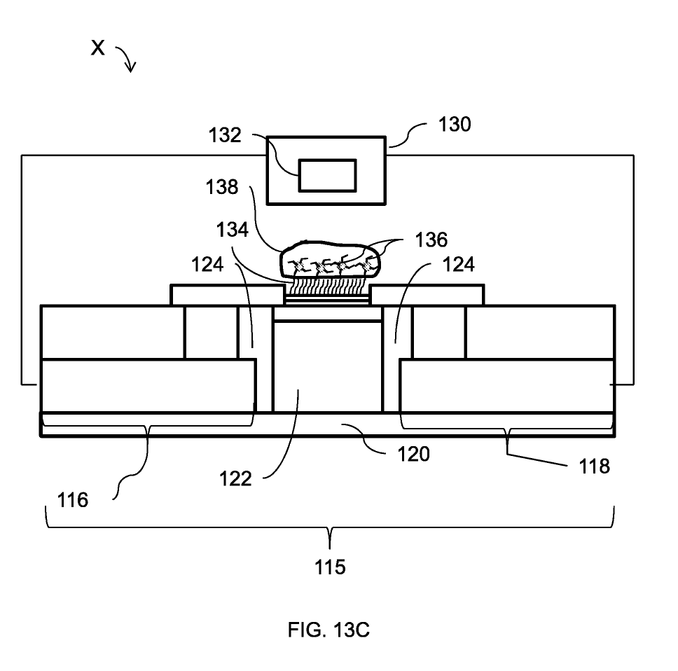

FIGS. 13A-13C illustrate another embodiment of a detection system 114. As illustrated in FIG. 13A, the detection system 114 is in the form of a thin film transistor (TFT) 115 coupled to a sensor 130. A source terminal 116 and a drain terminal 118 are formed on a body 120. The body 120 can be formed of any suitable material, such as a glass or silicon. A gate 122 is positioned between the source terminal 116 and the drain terminal 118 and spacers 124 are interposed between the gate 122 and the source terminal 116 and drain terminal 118 to prevent direct physical contact. An exposed channel 126 is positioned above the gate 122. The channel 126 can be formed of Silicon, indium, gallium, zinc, and oxygen (IGZO) semiconductor, or any other suitable semiconductor. The channel 126 includes a functionalized sensor surface 128, similar to the functionalized sensor surface 92 described above with respect to FIGS. 9A-9B. A sensor 130, having a microcontroller 132, is coupled to the source terminal 116 and the drain terminal 118 to monitor the state of the transistor, such as monitoring voltage or conductivity.

As described above with respect to FIG. 10, the detection system 114 can be used to detect the presence of target molecules. In this embodiment, the target molecules 134 are bound to the functionalized sensor surface 128 (FIG. 13A). As illustrated by FIG. 13B, catalytic nanoparticles 136 are hybridized to the bound target molecules 134. The hybridization of the catalytic nanoparticles 136 produces a second or top gate above the channel 126 and gate 122. Optionally, the catalytic nanoparticles can serve as nucleation sites for the development of a conductive film 138 (FIG. 13C) to further develop the top gate.

The development of the top gate serves to change the conductive state of the transistor 115. By monitoring the state of the transistor 115 via the sensor 130, the presence of the target molecules 134 can be detected. For example, if changes in the conductive state of the transistor 115 are detected, the presence of the target molecules 134 is detected. If there are not changes in the conductive state of the transistor 115, the top gate has not developed and no target molecules 134 are detected.

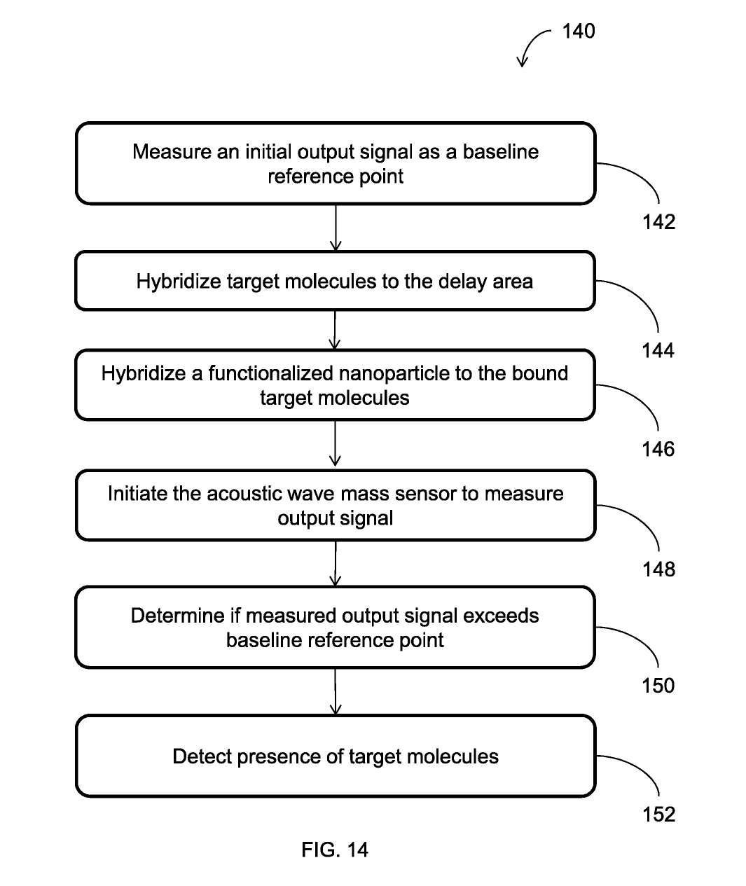

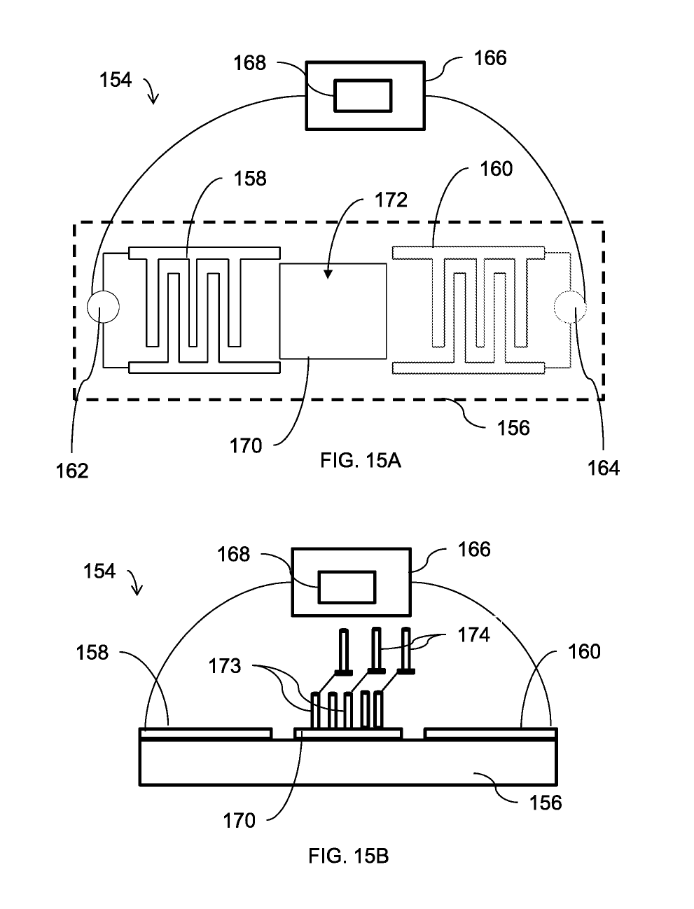

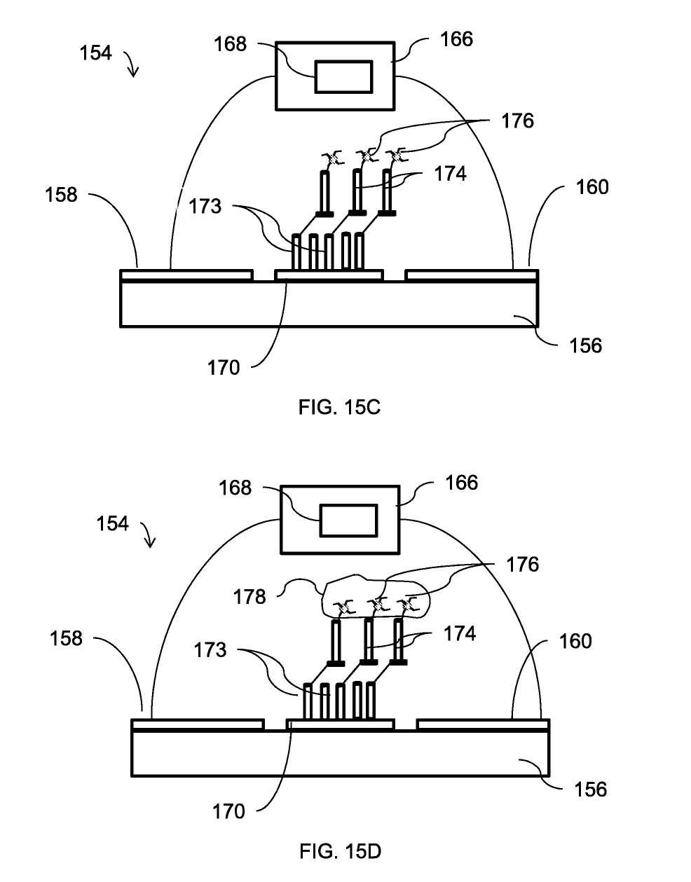

FIG. 14 illustrates another method 140 for detecting a target molecule. In an example, the method 140 can be used to detect a target molecule with a detection system, such as the detection system 154 illustrated by FIGS. 15A-15D. The detection system 154 includes a substrate 156 on which a first transducer 158 and a second transducer 160 are positioned. A signal is input 162 at the first transducer 158 and a signal is output 164 at the second transducer 160. A sensor 166, having a microcontroller 168 is coupled to the signal input 162 and the signal output 164 to input the signal and measure or monitor the output signal 164. In an embodiment, the sensor 166 is an acoustic wave mass sensor.

A functionalized delay area 170 is positioned on the substrate 156 between the first transducer 158 and the second transducer 160. In an embodiment, the surface 172 of the delay area 170 is functionalized with a bio-specific coating 173 (FIG. 15B), such as nucleic acid primers or proteins.

Returning to FIG. 14, at block 142, an initial output signal is measured as a baseline reference point. At block 144, target molecules 174 are hybridized or bound to the bio-specific coating 173 (FIG. 15B). For example, a sample containing the target molecules 174 can be introduced to the delay area 170 and allowed to interact with the coating 173. The sample can be rinsed to leave only the bound target molecules 174.

At block 146 (FIG. 14), functionalized nanoparticles 176 are hybridized to the bound target molecules 174 (FIG. 15C). In an example, the functionalized nanoparticles 176 are catalytic nanoparticles, such as gold clusters, as discussed above. Optionally, the functionalized nanoparticles can act as nucleation sites for the development of a film 178 (FIG. 15D) to increase the mass of the delay area 170.

At block 148 (FIG. 14) the acoustic wave mass sensor 166 is initiated to measure the output signal. At block 150, the sensor 166 determines if the measured output signal exceeds the baseline reference point to detect, at block 152, the presence of target molecules. When the measured output signal does exceed the baseline reference point, the target molecules are detected. When the measured output signal does not exceed the baseline reference point, the target molecules are not detected.

While the detection systems 80, 114, 154 have been discussed in terms of independent detection systems, it is to be under stood that the detection systems 80, 114, 154 can be incorporated in other systems, such as the portable assay system 10 or disposable assay cartridge 20 described above with respect to FIGS. 1-4.

Possible advantages of the above described method include improved sensitivity of target molecule detection and improved detection of small quantities of target molecules.

While the present invention has been particularly shown and described with reference to certain exemplary embodiments, it will be understood by one skilled in the art that various changes in detail may be effected therein without departing from the spirit and scope of the invention that can be supported by the written description and drawings. Further, where exemplary embodiments are described with reference to a certain number of elements it will be understood that the exemplary embodiments can be practiced utilizing either less than or more than the certain number of elements.

The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

To the extent that the claims recite the phrase “at least one of” in reference to a plurality of elements, this recitation is intended to mean at least one or more of the listed elements, and is not limited to at least one of each element. For example, “at least one of an element A, element B, and element C,” is intended to indicate element A alone, or element B alone, or element C alone, or any combination thereof. “At least one of element A, element B, and element C” is not intended to be limited to at least one of an element A, at least one of an element B, and at least one of an element C.

### PARTS LIST

10 portable assay system
14 processor
18 rotor
18P port
20 disposable assay cartridge
22 cartridge body
22B syringe barrel
24 linear actuator
26 plunger shaft
28 elastomeric plunger
30 central chamber
32 assay chamber
34 assay chamber
40 channel
42 channel
44 bottom panel
50 aperture
70 functionalized sensor surface
72 capture molecule
74 target molecule
76 catalytic nanoparticle
78 conductive film
80 detection system
82 well
84 source terminal
86 drain terminal
88 sensor
90 microcontroller
92 functionalized sensor surface
94 spacer
96 gate
97 method
98-106 method blocks
108 target molecule
110 catalytic nanoparticles
112 conductive film
114 detection system
115 thick film transistor
116 source terminal
118 drain terminal
120 body
122 gate
124 spacers
126 channel
128 functionalized sensor surface
130 sensor
132 microcontroller
134 target molecule
136 catalytic nanoparticles
138 conductive film
140 method
142-152 method blocks
154 detection system
156 substrate
158 first transducer
160 second transducer
162 signal input
164 signal output
166 sensor
168 microcontroller
170 delay area
172 delay area surface
173 coating
174 target molecules
176 functionalized nanoparticles
178 film

What is claimed is:

1. A system for detecting a target molecule in a sample, comprising:
a source terminal;
a drain terminal;
a sensor coupled to the source terminal and the drain terminal, the sensor configured to monitor electrical signals across the source terminal and drain terminal;
a gate positioned adjacent to one of the source terminal and the drain terminal and extending partially across a gap between the source terminal and drain terminal; and
a sensor surface exposed between the gate and one of the source terminal and the drain terminal, the sensor surface comprising a functionalized sensor surface configured to bind the target molecule.

2. The system of claim 1, further comprising a well on which the source terminal and drain terminal are positioned.

3. The system of claim 1, wherein the target molecule is configured to bind a catalytic nanoparticle when the target molecule is bound to the functionalized sensor surface, and wherein the catalytic nanoparticle acts as a gate material to fill a distance across the functionalized sensor surface between the gate and one of the source terminal and the drain terminal.

4. The system of claim 3, wherein the catalytic nanoparticle is further configured to act as a nucleation site for development of a conductive film.

5. The system of claim 3, wherein when the catalytic nanoparticle fills the distance across the functionalized sensor surface, the sensor is configured to monitor any resulting changes in the electrical signals.

6. The system of claim 5, wherein the sensor is configured to detect a presence of the target molecule when changes in the electrical signals are detected.

7. A system for detecting a target molecule in a sample, comprising:
a source terminal;
a drain terminal;
a sensor coupled to the source terminal and the drain terminal, the sensor configured to monitor electrical signals across the source terminal and drain terminal;
a gate positioned between the source terminal and the drain terminal; and
a channel positioned above the gate, the channel comprising a functionalized sensor surface configured to bind the target molecule.

8. The system of claim 7, wherein the target molecule is configured to bind a catalytic nanoparticle when the target molecule is bound to the functionalized sensor surface, and wherein the catalytic nanoparticle acts as a top gate.

9. The system of claim 8, wherein the catalytic nanoparticle is further configured to act as a nucleation site for development of a conductive film.

10. The system of claim 8, wherein the sensor is configured to monitor any changes in the electrical signals from development of the top gate and wherein the sensor is configured to detect the target molecule when a change in the electrical signals is detected.

11. The system of claim 7, further comprising a body on which the source terminal, drain terminal, and gate are positioned.

12. The system of claim 7, further comprising a first spacer between the gate and the source terminal and a second spacer between the gate and the drain terminal.

13. A system for detecting a target molecule in a sample, comprising:
a substrate;
a first transducer positioned on the substrate, the first transducer having a signal input;
a second transducer positioned on the substrate, the second transducer having a signal output;
a sensor coupled to the signal input to input a signal and to the signal output to measure an output signal; and
a delay area positioned between the first transducer and the second transducer, the delay area having a functionalized coating configured to bind the target molecule.

14. The system of claim 13, wherein the target molecule is configured to bind a functionalized nanoparticle when the target molecule is bound to the functionalized coating.

15. The system of claim 14, wherein the functionalized nanoparticle is a catalytic nanoparticle and wherein the catalytic nanoparticle is configured to act as a nucleation site for development of a film.

16. The system of claim 14, wherein the sensor is an acoustic wave mass sensor and wherein the output signal is indicative of a mass of the target molecule and the functionalized nanoparticle.

17. The system of claim 14, wherein the sensor is configured to:
measure the output signal;
compare the measured output signal to a baseline signal; and
detect the target molecule when the measured output signal exceeds the baseline signal.
